(19) United States
(12) Patent Application Publication
(10) Pub. No.: US 2013/0162914 A1
(43) Pub. Date: Jun. 27, 2013

(54) ELECTRONIC APPARATUS, PORTABLE COMPUTER, AND TELEVISION

(71) Applicant: Norikazu NAGASAWA, Ome-shi (JP)

(72) Inventor: Norikazu NAGASAWA, Ome-shi (JP)

(73) Assignee: KABUSHIKI KAISHA TOSHIBA, Tokyo (JP)

(21) Appl. No.: 13/612,577

(22) Filed: Sep. 12, 2012

(30) Foreign Application Priority Data
Dec. 27, 2011 (JP) 2011-286522

(51) Int. Cl. H04N 5/66; G06F 1/16; H05K 7/06

(52) U.S. Cl. 348/739; 361/752; 361/679.27; 348/E05.133

(57) ABSTRACT

According to one embodiment, an electronic apparatus includes a housing, a display in the housing, a module in the housing, and a member attached to an end of the display. The member is configured to support the module and includes a cutout portion at an inner side of an end region of the module in a direction substantially parallel to the end of the display.

### CROSS-REFERENCE TO RELATED APPLICATIONS

This application is based upon and claims the benefit of priority from prior Japanese Patent Application No. 2011-286522, filed Dec. 27, 2011; the entire contents of which are incorporated herein by reference.

### FIELD

Embodiments described herein relate generally to electronic apparatuses including portable computers and televisions.

### BACKGROUND

A chassis member including a supporting portion has been proposed.

### BRIEF DESCRIPTION OF THE DRAWINGS

A general architecture that implements the various features of the embodiments will now be described with reference to the drawings. The drawings and the associated descriptions are provided to illustrate the embodiments and not to limit the scope of the invention.

FIG. 1 is an exemplary perspective view of a portable computer according to a first embodiment;

FIG. 2 is an exemplary perspective view of the internal structure of a display unit illustrated in FIG. 1;

FIG. 3 is an exemplary perspective view of a reinforcing structure illustrated in FIG. 2;

FIG. 4 is an exemplary cross-sectional view of the reinforcing structure taken along the line F4-F4 of FIG. 3;

FIG. 5 is an exemplary perspective view of a hinge fixing portion illustrated in FIG. 2;

FIG. 6 is an exemplary plan view schematically illustrating the reinforcing structure illustrated in FIG. 2;

FIG. 7 is an exemplary plan view schematically illustrating a reinforcing structure according to a second embodiment;

FIG. 8 is an exemplary perspective view of a reinforcing structure according to a third embodiment;

FIG. 9 is an exemplary cross-sectional view of the reinforcing structure taken along the line F9-F9 of FIG. 8;

FIG. 10 is an exemplary cross-sectional view of a reinforcing structure according to a fourth embodiment;

FIG. 11 is an exemplary perspective view of a reinforcing structure according to a fifth embodiment;

FIG. 12 is an exemplary cross-sectional view of a reinforcing structure according to a sixth embodiment;

FIG. 13 is an exemplary perspective view of a reinforcing structure according to a seventh embodiment;

FIG. 14 is an exemplary front view of a television according to an eighth embodiment;

FIG. 15 is an exemplary cross-sectional view of the television illustrated in FIG. 14;

FIG. 16 is an exemplary plan view schematically illustrating a reinforcing structure illustrated in FIG. 15;

FIG. 17 is an exemplary perspective view of a reinforcing structure related to the first to eighth embodiments; and

FIG. 18 is an exemplary plan view schematically illustrating the reinforcing structure related to the first to eighth embodiments.

### DETAILED DESCRIPTION

Various embodiments will be described hereinafter with reference to the accompanying drawings.

In general, according to one embodiment, an electronic apparatus comprises a housing, a display in the housing, a module in the housing, and a member attached to an end of the display. The member is configured to support the module and comprises a cutout portion at an inner side of an end region of the module in a direction substantially parallel to the end of the display.

Hereinafter, embodiments will be described with reference to the drawings.

### First Embodiment

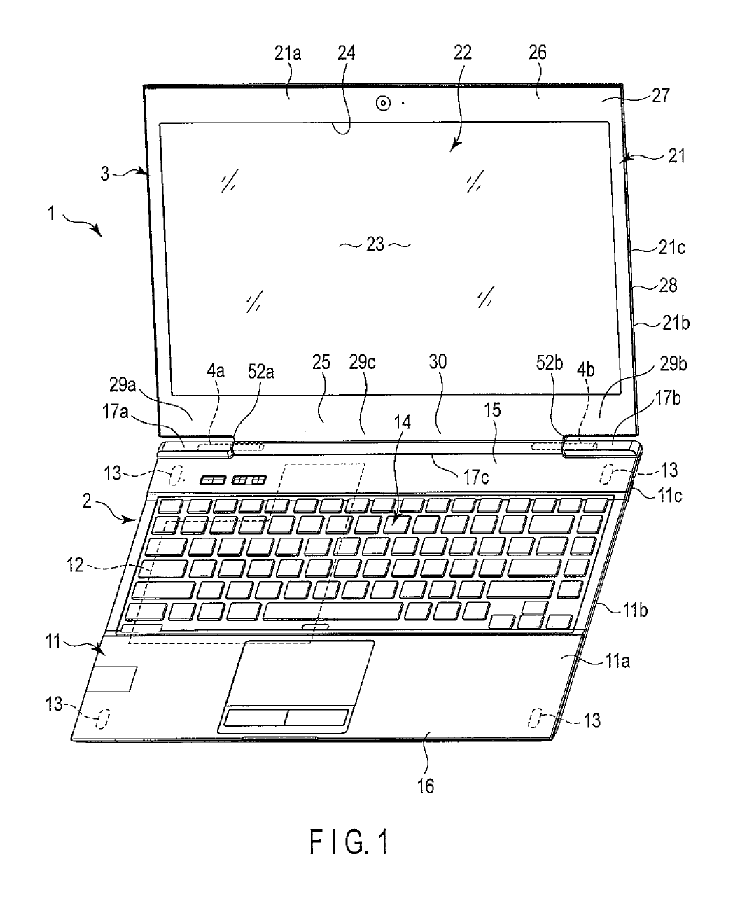

FIGS. 1 to 6 illustrate an electronic apparatus 1 according to a first embodiment. As illustrated in FIG. 1, the electronic apparatus 1 is, for example, a notebook-type portable computer (hereinafter, referred to as a notebook PC).

Electronic apparatuses, to which this embodiment and the second to eighth embodiments described below can be applied, are not limited to notebook PCs. The first to eighth embodiments can be widely applied to mobile phones (including smart phones), tablet terminals (i.e., slate PCs), televisions, and other electronic apparatuses.

As illustrated in FIG. 1, the electronic apparatus 1 includes a first unit 2, a second unit 3, a first hinge 4a, and a second hinge 4b. The first unit 2 is, for example, a main unit provided with a main board. The first unit 2 includes a first housing 11. The first housing 11 includes, for example, a circuit board 12 as the main board.

The first housing 11 includes an upper wall 11a, a lower wall 11b, and a circumferential wall 11c and has a flat box shape. In the specification, the upper, lower, left, and right sides are defined in the viewing direction of the user. The side closer to the user is defined as the “front side” and the side farther from the user is defined as the “rear side”.

The lower wall 11b faces a desk surface when the electronic apparatus 1 is placed on a desk (i.e., mounting surface, or outer surface). For example, a plurality of leg portions 13 (i.e., supporters, or supporting portions) that come into contact with the desk surface are provided on the lower wall 11b. The upper wall 11a is opposite to the lower wall 11b with a space therebetween and extends substantially in parallel to the lower wall 11b. An input unit 14 (i.e., input receiving unit) is provided on the upper wall 11a. An example of the input unit 14 is a keyboard, but the input unit 14 is not limited thereto. For example, the input unit 14 may be a touch panel (i.e., touch sensor).

The circumferential wall 11c extends in a direction crossing the lower wall 11b and connects the edge of the lower wall 11b and the edge of the upper wall 11a. The first housing 11 includes a first end 15 and a second end 16. The first end 15 is, for example, the rear end. The second end 16 is opposite to the first end 15 and is, for example, the front end.

As illustrated in FIG. 1, a first projection 17a and a second projection 17b are provided as a pair of projections at the first end 15. The projections 17a and 17b protrude upward from the upper wall 11a of the first housing 11. The pair of projections 17a and 17b are separately provided at both ends (e.g., left and right ends) of the first housing 11 and are separated from each other. In this way, a concave portion 17c is provided between the pair of projections 17a and 17b.

As illustrated in FIG. 1, the second unit 3 is a display unit. The second unit 3 includes a second housing 21 and a display device 22 which is accommodated in the second housing 21. The second housing 21 includes a front wall 21a, a rear wall 21b, and a circumferential wall 21c and has a flat box shape. The display device 22 includes a display screen 23. An opening 24 through which the display screen 23 is exposed is provided in the front wall 21a. The rear wall 21b is opposite to the front wall 21a. The circumferential wall 21c connects the edge of the front wall 21a and the edge of the rear wall 21b.

The second housing 21 includes a first end 25 and a second end 26. The first end 25 is, for example, the lower end. The second end 26 is opposite to the first end 25 and is, for example, the upper end. In the present specification, the upper and lower sides are defined based on the standing-up position of the second unit 3.

The second housing 21 includes a mask 27 and a cover 28. The mask 27 includes the front wall 21a. The cover 28 includes the rear wall 21b and the circumferential wall 21c. The mask 27 and the cover 28 are combined to form the second housing 21.

As illustrated in FIG. 1, the hinges 4a and 4b are fixed to the first end 15 of the first housing 11 and the first end 25 of the second housing 21, respectively, and connect the first housing 11 and the second housing 21 so as to be rotatable (i.e., openable). In this way, the second housing 21 can be rotated between a first state where the first housing 11 and the second housing 21 overlap each other and a second state where the first housing 11 and the second housing 21 are opened. At the second state, the input unit 14 and the display screen 23 are exposed to the outside. At the first state, the input unit 14 and the display screen 23 are hidden from the outside.

As illustrated in FIG. 1, the second housing 21 includes a first portion 29a, a second portion 29b, and a third portion 29c. The first portion 29a is disposed at the left end of the second housing 21 and faces the first projection 17a. The second portion 29b is disposed at the right end of the second housing 21 and faces the second projection 17b. The third portion 29c is disposed between the first portion 29a and the second portion 29b and faces the concave portion 17c.

The third portion 29c protrudes from the first portion 29a and the second portion 29b to the first housing 11. A part of the third portion 29c is provided between the first projection 17a and the second projection 17b. The third portion 29c forms an example of a protrusion 30 which protrudes toward the first housing 11 and into which the hinges 4a and 4b are inserted.

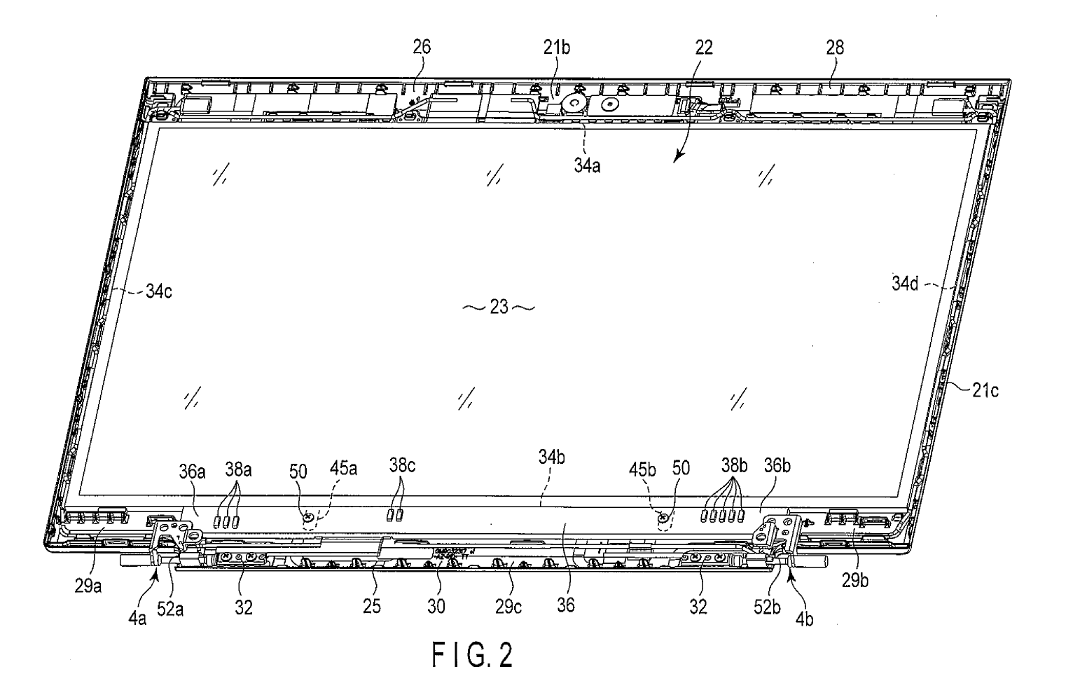

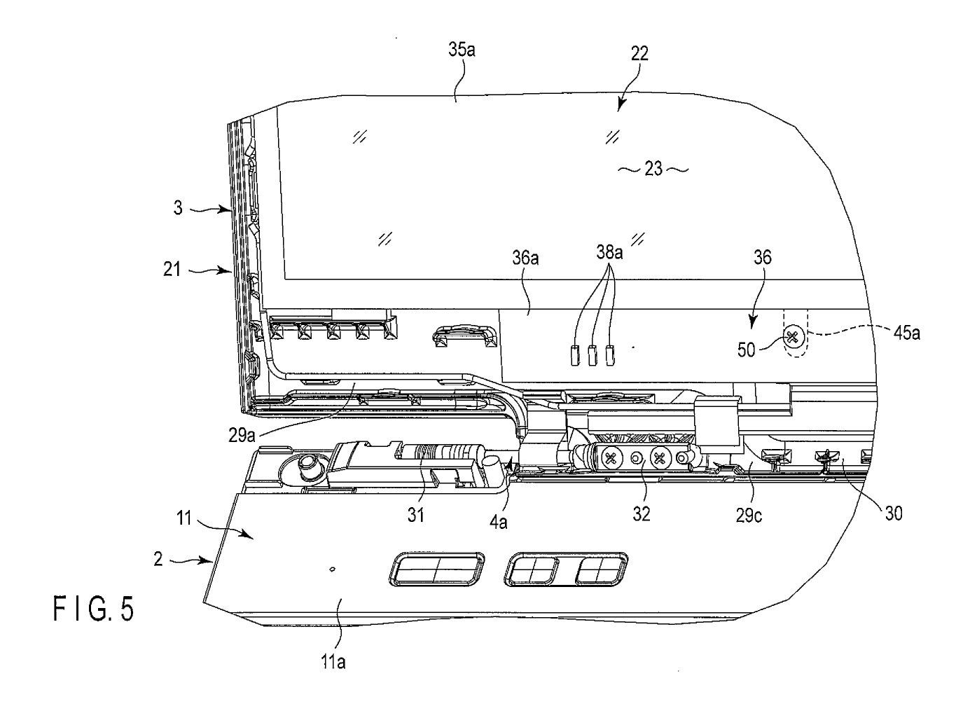

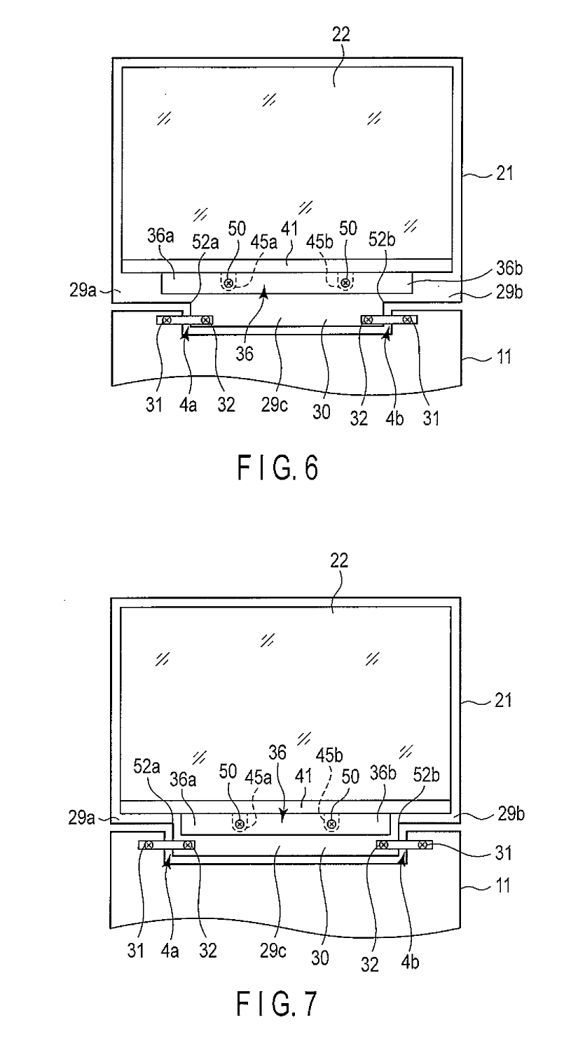

As illustrated in FIGS. 1 and 2, the first hinge 4a and the second hinge 4b extend substantially in parallel to the first end 15 of the first housing 11. The first hinge 4a extends between the first projection 17a of the first housing 11 and the third portion 29c of the second housing 21. The second hinge 4b extends between the second projection 17b of the first housing 11 and the third portion 29c of the second housing 21. Each of the first hinge 4a and the second hinge 4b includes a first fixing portion 31 attached to the first housing 11 and a second fixing portion 32 attached to the second housing 21 (see FIGS. 5 and 6).

As illustrated in FIG. 2, each of the first hinge 4a and the second hinge 4b is fixed to the rear wall 21b (i.e., cover 28) of the second housing 21. In this embodiment, the first hinge 4a and the second hinge 4b are fixed in the third portion 29c (i.e., in the protrusion 30) of the second housing 21. In this embodiment, the first hinge 4a and the second hinge 4b are not fixed to a region other than the third portion 29c. However, the position where the hinges 4a and 4b are fixed is not limited thereto.

Next, a reinforcing structure of the display device 22 will be described.

The display device 22 is an example of a “display”, a “display unit”, a “display device”, or a “display module”. The display device 22 is, for example, a liquid crystal display (LCD), but is not limited thereto. In addition, the display device 22 is not limited to a rigid display device, but may be a flexible display. The display device 22 includes, for example, a glass cell and a backlight.

As illustrated in FIG. 2, the display device 22 is formed in a substantially rectangular shape and includes four sides (i.e., four ends). The four sides include an upper side 34a, a lower side 34b, a left side 34c, and a right side 34d. The upper side 34a and the lower side 34b extend substantially in the horizontal direction (e.g., the longitudinal direction of the display device 22). The left side 34c and the right side 34d extend in a direction crossing (e.g., substantially perpendicular to) the upper side 34a and the lower side 34b. The left side 34c and the right side 34d extend substantially in the vertical direction and connect the upper side 34a and the lower side 34b.

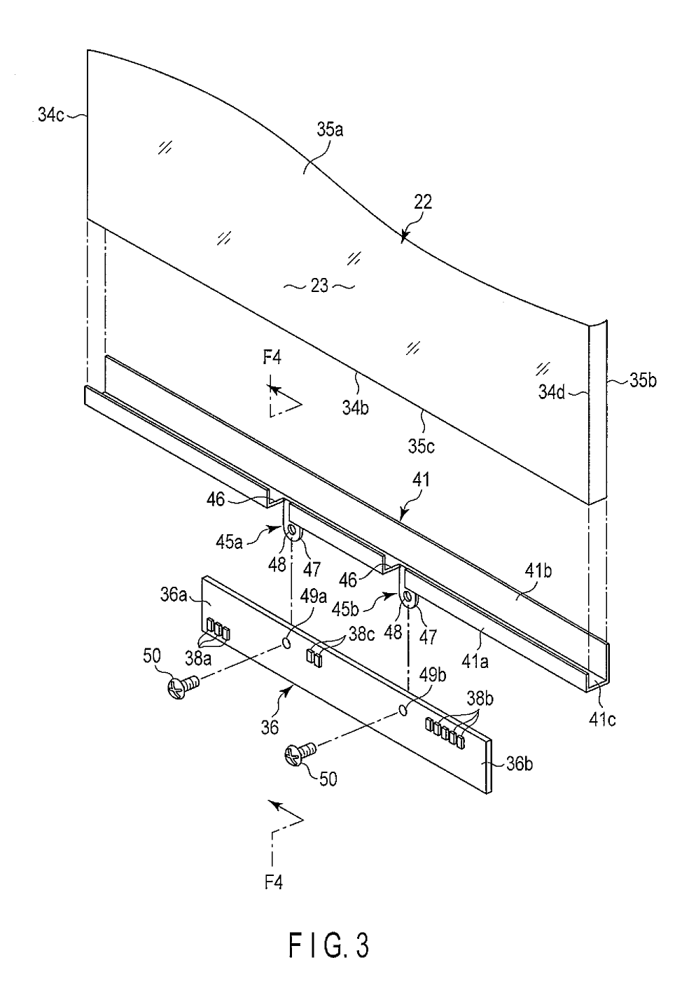

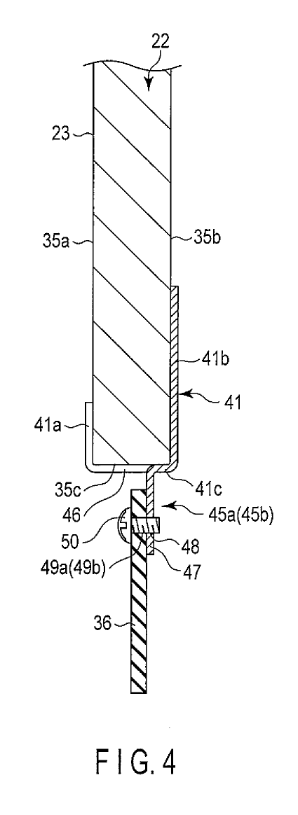

As illustrated in FIGS. 3 and 4, the display device 22 includes a first surface 35a, a second surface 35b, and a third surface 35c. The first surface 35a is, for example, a front surface and includes the display screen 23. The second surface 35b is opposite to the first surface 35a and is, for example, a rear surface (i.e., back surface). The second surface 35b extends substantially in parallel to the first surface 35a. The third surface 35c is a lower surface, for example. The third surface 35c extends between the first surface 35a and the second surface 35b in a direction crossing (e.g., substantially perpendicular to) the first surface 35a and the second surface 35b.

As illustrated in FIG. 3, a circuit board 36 is connected to the display device 22. The circuit board 36 is an example of a “module”. The “module” is not limited to the circuit board connected to the display device 22. The “module” may be a circuit board which is provided independently from the display device 22 or may be other components.

The circuit board 36 is accommodated in the second housing 21. The circuit board 36 includes, for example, a circuit for driving the display device 22. The circuit board 36 is electrically connected to the display device 22 via a flexible circuit board, for example. An example of the flexible circuit board is a chip on film (COF).

If there is not any structure for holding the circuit board 36, a load is imparted on a connection portion (e.g., a flexible circuit board) between the circuit board 36 and the display device 22. Therefore, a holding structure (which will be described below) for holding the circuit board 36 is provided.

As illustrated in FIGS. 2 to 4, the circuit board 36 is provided at a position where it does not overlap the first surface 35a and the second surface 35b of the display device 22. The circuit board 36 is adjacent to the display device 22 in a direction crossing (e.g., substantially perpendicular to) the thickness direction of the display device 22. The circuit board 36 is parallel to the display device 22. The circuit board 36 is disposed below the third surface 35c of the display device 22. The circuit board 36 is adjacent to the lower side 34b of the display device 22 and is arranged along the lower side 34b.

As illustrated in FIG. 4, the circuit board 36 is provided substantially in parallel to the first surface 35a and is disposed within the thickness range of the display device 22. The expression “disposed within the thickness range of the display device” means that the circuit board 36 is disposed between the extension line of the first surface 35a and the extension line of the second surface 35b of the display device 22. In this way, it is possible to reduce the thickness of the second housing 21 required to accommodate the display device 22.

As illustrated in FIG. 3, the circuit board 36 includes a first end 36a and a second end 36b. The first end 36a and the second end 36b are the ends of the circuit board 36 in the longitudinal direction thereof. The longitudinal direction of the circuit board 36 is substantially parallel to the lower side 34b of the display device 22. The second end 36b is opposite to the first end 36a. A plurality of components 38a, 38b, and 38c (e.g., electronic components) are mounted on the circuit board 36.

As illustrated in FIGS. 3 and 4, a reinforcing member 41 is attached to the display device 22. The reinforcing member 41 is an example of a “reinforcing portion”, a “metal portion”, a “holder”, a “metal plate member”, or a “member”. The reinforcing member 41 is attached to at least one side (i.e., an end) of the display device 22.

The reinforcing member 41 may be provided around the display device 22 or it may be provided at one side or a plurality of sides. FIGS. 3 and 4 illustrate a part of the reinforcing member 41 attached to the lower side 34b (i.e., lower end) of the display device 22. For example, in FIG. 2, the reinforcing member 41 is combined with other members. For example, the reinforcing member 41 improves the strength of the display device 22 and integrally holds the glass cell and the backlight of the display device 22.

As illustrated in FIGS. 2 to 4, the reinforcing member 41 is attached to, for example, the lower side 34b of the display device 22 and extends along the lower side 34b. The length of the reinforcing member 41 is substantially equal to that of the display device 22 in the longitudinal direction. That is, the reinforcing member 41 is provided substantially over the entire width of the display device 22. The shape of the reinforcing member 41 is not limited to the above, but the reinforcing member 41 may be provided so as to correspond to a portion of the lower side 34b.

As illustrated in FIGS. 3 and 4, the reinforcing member 41 is, for example, a metal plate (i.e., metal member) which is bent in a U-shape. The reinforcing member 41 includes a first portion 41a, a second portion 41b, and a third portion 41c. The first portion 41a faces the first surface 35a of the display device 22. The second portion 41b faces the display device 22 from an opposite side to the first portion 41a. The second portion 41b faces the second surface 35b of the display device 22. The third portion 41c extends between the first portion 41a and the second portion 41b. The third portion 41c faces the third surface 35c of the display device 22.

In other words, the third portion 41c extends substantially in parallel to the third surface 35c of the display device 22. The first portion 41a rises from the front end of the third portion 41c and extends upward. The second portion 41b rises from the rear end of the third portion 41c and extends upward. The length of each of the first to third portions 41a, 41b, and 41c is substantially equal to that of the display device 22 in the longitudinal direction. That is, each of the first to third portions 41a, 41b, and 41c is provided substantially over the entire width of the display device 22.

As illustrated in FIGS. 3 and 4, the reinforcing member 41 includes supporting portions 45a and 45b (i.e., a first supporting portion 45a and a second supporting portion 45b) to which the circuit board 36 is attached. When the circuit board 36 is held by the reinforcing member 41, a load is less likely to be imparted on the connection portion between the circuit board 36 and the display device 22, as compared to a structure without a holding structure. Each of the supporting portions 45a and 45b is an example of a “fixing portion”, an “attachment portion”, or a “portion”.

As illustrated in FIGS. 3 and 4, each of the first supporting portion 45a and the second supporting portion 45b is formed by cutting at least a part of the first portion 41a and bending the cut part to the side opposite to the display device 22 (e.g., bending the cut part straight). That is, each of the first supporting portion 45a and the second supporting portion 45b is formed by cutting at least a part of the first portion 41a and stretching the cut part.

In this embodiment, each of the first supporting portion 45a and the second supporting portion 45b is formed by cutting a part of the first portion 41a and a part of the third portion 41c of the reinforcing member 41 and bending the cut parts to the side opposite to the display device 22 (e.g., bending the cut parts straight).

As illustrated in FIG. 3, the first supporting portion 45a and the second supporting portion 45b are separately provided in the longitudinal direction of the circuit board 36. The first supporting portion 45a and the second supporting portion 45b are independently provided. That is, the second supporting portion 45b and the first supporting portion 45a are formed by cutting different parts of the reinforcing member 41 and bending the cut parts.

As illustrated in FIG. 3, each of the first supporting portion 45a and the second supporting portion 45b includes a cutout portion 46 which is formed by cutting and a projection 47 (i.e., a tongue portion, an attachment portion, or a fixing portion) which is formed by bending. A fixing portion 48 to which the circuit board 36 is fixed is provided in the projection 47.

An example of the fixing portion 48 is a screw hole. The circuit board 36 includes through holes 49a and 49b which are provided at the positions corresponding to the fixing portions 48. That is, the circuit board 36 includes the first through hole 49a corresponding to the fixing portion 48 of the first supporting portion 45a and the second through hole 49b corresponding to the fixing portion 48 of the second supporting portion 45b. Screws 50 are inserted into the fixing portions 48 of the projections 47 through the through holes 49a and 49b of the circuit board 36. In this way, the circuit board 36 is fixed to the reinforcing member 41.

As illustrated in FIG. 4, the first supporting portion 45a and the second supporting portion 45b are not provided in the end regions (i.e., the first end 36a and the second end 36b) of the circuit board 36, but are provided at the positions which are inner side of the end regions of the circuit board 36. That is, the first supporting portion 45a and the second supporting portion 45b are away from the end regions (i.e., the first end 36a and the second end 36b) of the circuit board 36 and are disposed closer to a central portion of the circuit board 36 than the end regions.

The components 38a, 38b, and 38c mounted on the circuit board 36 include the first component 38a, the second component 38b, and the third component 38c. The first component 38a is provided between the first end 36a and the first through hole 49a. The second component 38b is provided between the second end 36b and the second through hole 49b. The third component 38c is provided between the first through hole 49a and the second through hole 49b.

As illustrated in FIGS. 2 and 4, the first supporting portion 45a is disposed at a region further inward (e.g., a region closer to the central portion of the circuit board 36) than the end region of the circuit board 36 in a direction (e.g., a direction in which the lower side 34b extends) which is substantially parallel to the lower side 34b of the display device 22.

In other words, the first supporting portion 45a is disposed at a region further inward than the first component 38a of the circuit board 36 in the direction substantially parallel to the lower side 34b of the display device 22. That is, the first supporting portion 45a is greater distant from the end (i.e., first end 36a) of the circuit board 36 than the first component 38a in the direction substantially parallel to the lower side 34b of the display device 22.

Similarly, the second supporting portion 45b is disposed at a region further inward (e.g., a region closer to the central portion of the circuit board 36) than the end region of the circuit board 36 in the direction substantially parallel to the lower side 34b of the display device 22.

In other words, the second supporting portion 45b is disposed at a region further inward than the second component 38b of the circuit board 36 in the direction substantially parallel to the lower side 34b of the display device 22. That is, the second supporting portion 45b is greater distant from the end (i.e., second end 36b) of the circuit board 36 than the second component 38b in the direction substantially parallel to the lower side 34b of the display device 22.

That is, the first supporting portion 45a and the second supporting portion 45b are disposed at the positions closer to the central portion of the circuit board 36 than the first end 36a and the second end 36b of the circuit board 36. The first supporting portion 45a and the second supporting portion 45b are disposed between the first component 38a and the second component 38b. In other words, the first component 38a is disposed between the first supporting portion 45a and the first end 36a of the circuit board 36. The second component 38b is disposed between the second supporting portion 45b and the second end 36b of the circuit board 36.

As illustrated in FIGS. 2, 5, and 6, in this embodiment, the first supporting portion 45a is greater distant from the first end 36a of the circuit board 36 than the second fixing portion 32 of the first hinge 4a in the direction substantially parallel to the lower side 34b of the display device 22. That is, the first supporting portion 45a is disposed at a region of the circuit board 36 further inward (e.g., a region closer to the central portion of the circuit board 36) than the second fixing portion 32 of the first hinge 4a in the direction substantially parallel to the lower side 34b of the display device 22. The second fixing portion 32 of the first hinge 4a is provided at a position (i.e., region) corresponding to the space between the first end 36a of the circuit board 36 and the first supporting portion 45a.

Similarly, the second supporting portion 45b is greater distant from the second end 36b of the circuit board 36 than the second fixing portion 32 of the second hinge 4b in the direction substantially parallel to the lower side 34b of the display device 22. That is, the second supporting portion 45b is disposed at a region of the circuit board 36 further inward (e.g., a region closer to the central portion of the circuit board 36) than the second fixing portion 32 of the second hinge 4b in the direction substantially parallel to the lower side 34b of the display device 22. The second fixing portion 32 of the second hinge 4b is provided at a position (i.e., region) corresponding to the space between the second end 36b of the circuit board 36 and the second supporting portion 45b.

As illustrated in FIGS. 2, 5, and 6, the protrusion 30 (i.e., third portion 29c) of the second housing 21 has a pair of corners 52a and 52b at the base end thereof. The first corner 52a is formed between the first portion 29a and the third portion 29c. The second corner 52b is formed between the second portion 29b and the third portion 29c.

In this embodiment, the first supporting portion 45a is greater distant from the first end 36a of the circuit board 36 than the first corner 52a of the protrusion 30 in the direction substantially parallel to the lower side 34b of the display device 22. That is, the first supporting portion 45a is disposed at a region of the circuit board 36 further inward (e.g., a region close to the central portion of the circuit board 36) than the first corner 52a in the direction substantially parallel to the lower side 34b of the display device 22.

Similarly, the second supporting portion 45b is greater distant from the second end 36b of the circuit board 36 than the second corner 52b of the protrusion 30 in the direction substantially parallel to the lower side 34b of the display device 22. That is, the second supporting portion 45b is disposed at a region of the circuit board 36 further inward (e.g., a region close to the central portion of the circuit board 36) than the second corner 52b in the direction substantially parallel to the lower side 34b of the display device 22.

According to this structure, it is possible to improve the strength of the electronic apparatus 1.

As illustrated in FIG. 17, when parts of the reinforcing member are cut and bent to form supporting portions 101a and 101b, the supporting portions 101a and 101b include cutout portions. Therefore, a U-shaped reinforcing structure is partially cut at the positions where the supporting portions 101a and 101b are provided. Therefore, strength is low at the positions where the supporting portions 101a and 101b are provided. As a result, the reinforcing member is likely to be bent at the positions where the supporting portions 101a and 101b are provided.

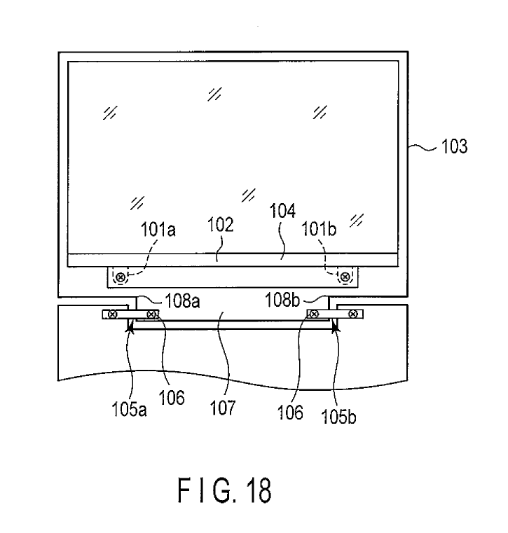

For comparison, FIG. 18 illustrates a structure in which a pair of supporting portions 101a and 101b including cutout portions are provided so as to correspond to both ends of a circuit board 102. In this case, the edge of a housing 103 is relatively close to the supporting portions 101a and 101b. Therefore, when an impact or stress is applied to the housing 103, the impact or stress is likely to be transmitted to the supporting portions 101a and 101b. As a result, the reinforcing member 104 is bent and it is difficult for the reinforcing member 104 to sufficiently protect the display device. A defect (e.g., damage) is likely to occur in the display device.

In contrast, in this embodiment, as illustrated in FIG. 6, in the reinforcing member 41, the cutout portions 46 (i.e., supporting portions 45a and 45b) are provided at the positions which are more inner than the end regions of the circuit board 36. Therefore, the distance between the supporting portions 45a and 45b and the edge of the housing 21 is large and an impact or stress applied to the housing 21 is less likely to be transmitted to the supporting portions 45a and 45b.

In other words, in the structure according to this embodiment, the impact or stress applied to the housing 21 is received by a portion (e.g., a portion with relatively high rigidity) of the reinforcing member 41 in which the cutout portions 46 are not provided. Therefore, the reinforcing member 41 can sufficiently protect the display device 22 and a defect is less likely to occur in the display device 22.

In this embodiment, the supporting portions 45a and 45b are disposed at a region of the circuit board 36 further inward than the components 38a and 38b. Therefore, the distance between the supporting portions 45a and 45b and the edge of the housing further increases. As a result, an impact or stress applied to the housing 21 is less likely to be transmitted to the supporting portions 45a and 45b.

In the structure illustrated in FIG. 18, the supporting portions 101a and 101b are disposed between the edge of the second housing 103 and second fixing portions 106 of hinges 105a and 105b. The second fixing portions 106 of the hinges 105a and 105b receive force to open and close the second housing 103 or an external impact or stress applied to the second housing 103. Therefore, a load is likely to be imparted on the region between the edge (e.g., the upper or side end) of the second housing 103 and the second fixing portions 106 of the hinges 105a and 105b.

In the structure illustrated in FIG. 18, since the supporting portions 101a and 101b are closer to the edge of the housing 103 than the second fixing portions 106 of the hinges 105a and 105b, a load (e.g., bending force or torsion) is likely to be imparted on the supporting portions 101a and 101b. Therefore, the reinforcing member 104 is bent and it is difficult for the reinforcing member 104 to sufficiently protect the display device. As a result, a defect is likely to occur in the display device.

In contrast, in this embodiment, as illustrated in FIG. 6, the supporting portions 45a and 45b are provided at an inner region of the circuit board 36 than the second fixing portions 32 of the hinges 4a and 4b. Therefore, a load imparted on the second fixing portions 32 of the hinges 4a and 4b is less likely to be applied to the supporting portions 45a and 45b. Therefore, the reinforcing member 41 can sufficiently protect the display device 22 and a defect is less likely to occur in the display device 22.

In the structure illustrated in FIG. 18, the supporting portions 101a and 101b are disposed in the vicinity of the corners 108a and 108b of the protrusion 107 of the second housing 103. When an impact or stress is applied to the second housing 103 and the second housing 103 is deformed, the stress is likely to be concentrated on the corners 108a and 108b of the protrusion 107. Therefore, a load is likely to be imparted on the supporting portions 101a and 101b. As a result, it is difficult for the reinforcing member 104 to sufficiently protect the display device and a defect is likely to occur in the display device.

In contrast, in this embodiment, as illustrated in FIG. 6, the supporting portions 45a and 45b are provided at an inner region of the circuit board 36 than the corners 52a and 52b of the protrusion 30 of the second housing 21. Therefore, the load imparted on the corners 52a and 52b of the protrusion 30 is less likely to be applied to the supporting portions 45a and 45b. Therefore, the reinforcing member 41 can sufficiently protect the display device 22 and a defect is less likely to occur in the display device 22.

### Second Embodiment

Next, an electronic apparatus 1 according to a second embodiment will be described with reference to FIG. 7. In this embodiment, components having the same or similar functions as those in the first embodiment are denoted by the same reference numerals and the description thereof will not be repeated. In addition, structures other than the following structure are the same as those in the first embodiment.

As illustrated in FIG. 7, this embodiment differs from the first embodiment in the position of the corners 52a and 52b of the protrusion 30 of the second housing 21. In this embodiment, the corners 52a and 52b of the protrusion 30 are disposed in the vicinity of the ends of a circuit board 36. In this structure, a large load is likely to be imparted on the ends of the circuit board 36. Therefore, supporting portions 45a and 45b are provided in an inner region of the circuit board 36, not in the end regions of the circuit board 36. In this way, it is possible to further improve the protection of the display device 22.

### Third Embodiment

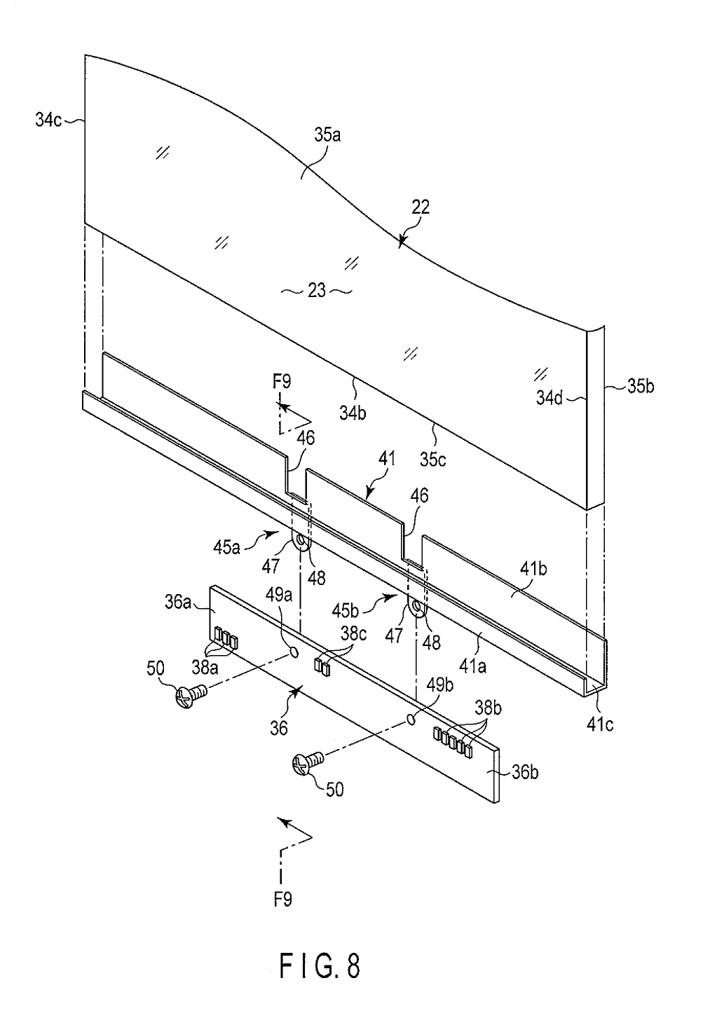

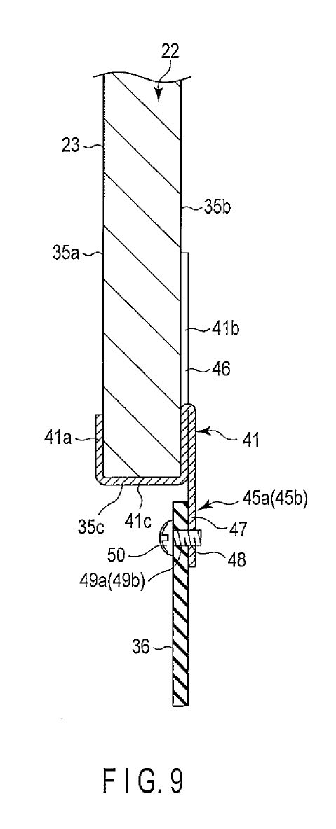

Next, an electronic apparatus 1 according to a third embodiment will be described with reference to FIGS. 8 and 9. In this embodiment, components having the same or similar functions as those in the first embodiment are denoted by the same reference numerals and the description thereof will not be repeated. In addition, structures other than the following structure are the same as those in the first embodiment.

As illustrated in FIGS. 8 and 9, it is easy to ensure the area of a second portion 41b of a reinforcing member 41 facing a second surface 35b (e.g., rear surface) of a display device 22, as compared to a first portion 41a. The length of the second portion 41b extending from a third portion 41c is more than that of the first portion 41a. The overlap area between the second portion 41b and the display device 22 is greater than that between the first portion 41a and the display device 22.

In this embodiment, a first supporting portion 45a and a second supporting portion 45b are formed by cutting and bending parts of the second portion 41b, instead of cutting and bending parts of the first portion 41a and the third portion 41c of the reinforcing member 41.

As illustrated in FIGS. 8 and 9, a cutout portion 46 does not reach the third portion 41c. That is, a part of the second portion 41b remains between the cutout portion 46 and the third portion 41c. Therefore, the second portion 41b extends over the entire length of the reinforcing member 41 without being partially cut. Therefore, a reinforcing structure (e.g., a U-shaped reinforcing structure) is maintained over the entire length of the reinforcing member 41.

In this embodiment, the supporting portions 45a and 45b are provided in the inner region of the circuit board 36, not in the end regions of the circuit board 36. However, from a different point of view, the supporting portions 45a and 45b according to this embodiment may be provided at the end region of the circuit board 36.

According to this structure, similarly to the first embodiment, it is possible to improve the strength of the electronic apparatus 1. In addition, in this embodiment, a part of the second portion 41b remains between the cutout portions 46 of the supporting portions 45a and 45b and the third portion 41c. In this way, the reinforcing structure (e.g., the U-shaped reinforcing structure) is maintained over the entire length of the reinforcing member 41 and it is possible to improve the strength of the reinforcing member 41.

### Fourth Embodiment

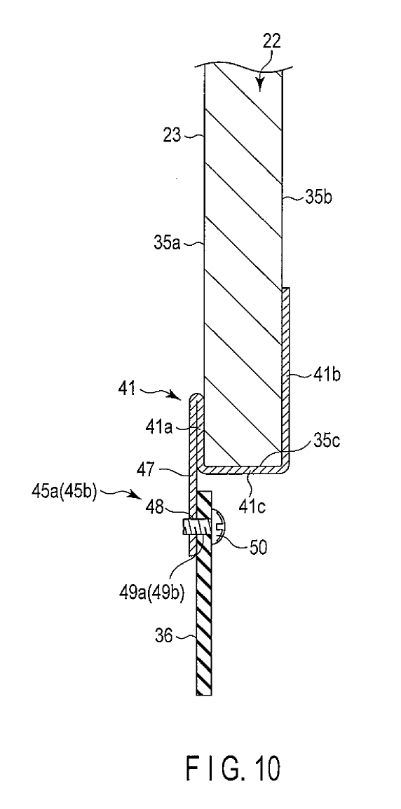

Next, an electronic apparatus 1 according to a fourth embodiment will be described with reference to FIG. 10. In this embodiment, components having the same or similar functions as those in the first embodiment are denoted by the same reference numerals and the description thereof will not be repeated. In addition, structures other than the following structure are the same as those in the first embodiment.

As illustrated in FIG. 10, in this embodiment, a reinforcing member 41 includes a large portion (e.g., projection) which is formed in a first portion 41a in advance. The large portion is bent (e.g., folded) in a direction in which it is away from a display device 22 to form supporting portions 45a and 45b. In this embodiment, a cutout portion 46 is not provided.

According to this structure, it is possible to improve the strength of the electronic apparatus 1. In this embodiment, a reinforcing structure (e.g., a U-shaped reinforcing structure) is maintained over the entire length of the reinforcing member 41 and it is possible to improve the strength of the reinforcing member 41.

### Fifth Embodiment

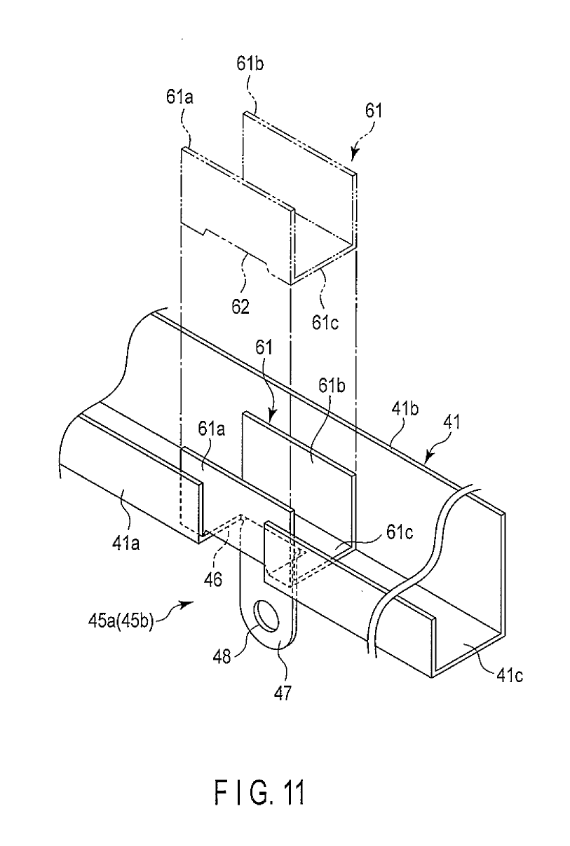

Next, an electronic apparatus 1 according to a fifth embodiment will be described with reference to FIG. 11. In this embodiment, components having the same or similar functions as those in the first embodiment are denoted by the same reference numerals and the description thereof will not be repeated. In addition, structures other than the following structure are the same as those in the first embodiment.

As illustrated in FIG. 11, in this embodiment, the electronic apparatus 1 includes a reinforcing component 61 (i.e., a reinforcing part, another part, another component, another member, a reinforcing member, or a member). The reinforcing component 61 is made of, for example, metal and has rigidity. The reinforcing component 61 is attached to a reinforcing member 41 and covers cutout portions 46. The reinforcing component 61 includes a recess 62 which is provided so as to avoid a projection 47.

For example, the reinforcing component 61 includes a first portion 61a, a second portion 61b, and a third portion 61c. The first portion 61a faces the first portion 41a of the reinforcing member 41. The second portion 61b faces the second portion 41b of the reinforcing member 41. The third portion 61c faces the third portion 41c of the reinforcing member 41. The reinforcing component 61 and the reinforcing member 41 cooperate with each other to maintain a reinforcing structure (e.g., U-shaped reinforcing structure) over the entire length of the reinforcing member 41.

According to this structure, it is possible to improve the strength of the electronic apparatus 1. In this embodiment, the reinforcing component 61 which covers the cutout portions 46 of the supporting portions 45a and 45b is attached to the reinforcing member 41. In this way, the reinforcing structure (e.g., a U-shaped reinforcing structure) is maintained over the entire length of the reinforcing member 41 and it is possible to improve the strength of the reinforcing member 41.

### Sixth Embodiment

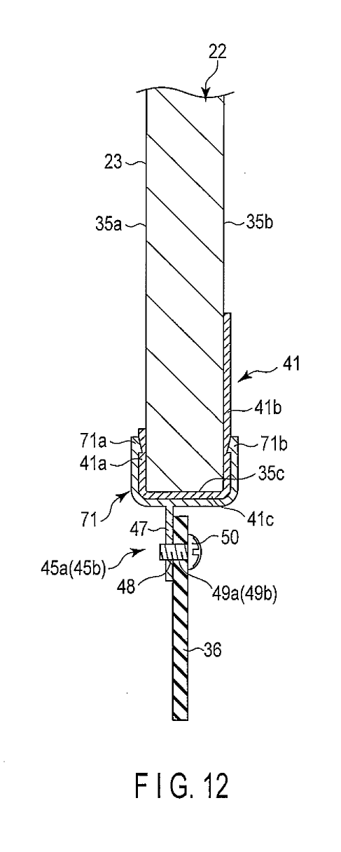

Next, an electronic apparatus 1 according to a sixth embodiment will be described with reference to FIG. 12. In this embodiment, components having the same or similar functions as those in the first embodiment are denoted by the same reference numerals and the description thereof will not be repeated. In addition, structures other than the following structure are the same as those in the first embodiment.

As illustrated in FIG. 12, in this embodiment, supporting portions 45a and 45b are not provided in a reinforcing member 41. An attachment member 71 (i.e., attachment, another member, a supporting member, a holding member, or a member) is attached to the reinforcing member 41. The supporting portions 45a and 45b are provided in the attachment member 71.

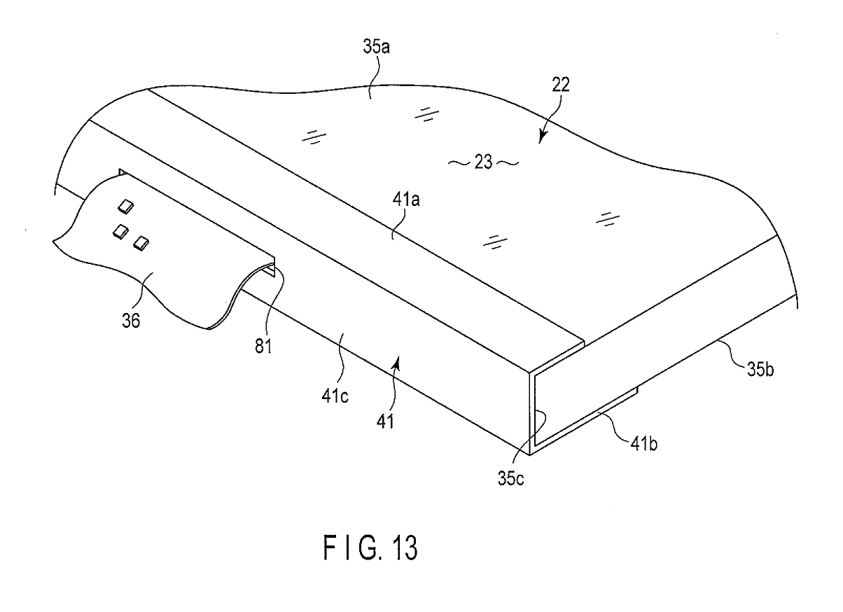

Specifically, as illustrated in FIG. 13, for example, the attachment member 71 includes a first portion 71a which is engaged with a first portion 41a of the reinforcing member 41 and a second portion 71b which is engaged with a second portion 41b of the reinforcing member 41. In this way, the attachment member 71 is attached to the reinforcing member 41. The attachment member 71 includes a projection 47 which protrudes in a direction in which it is separated from a display device 22.

According to this structure, it is possible to improve the strength of the electronic apparatus 1. In this embodiment, the cutout portion 46 is not provided in the reinforcing member 41. Therefore, a reinforcing structure (e.g., a U-shaped reinforcing structure) is maintained over the entire length of the reinforcing member 41 and it is possible to improve the strength of the reinforcing member 41.

### Seventh Embodiment

Next, an electronic apparatus 1 according to a seventh embodiment will be described with reference to FIG. 13. In this embodiment, components having the same or similar functions as those in the first embodiment are denoted by the same reference numerals and the description thereof will not be repeated. In addition, structures other than the following structure are the same as those in the first embodiment.

As illustrated in FIG. 13, in this embodiment, an opening 81 is provided in the third portion 41c of the reinforcing member 41. The circuit board 36 is inserted into an opening 81. The circuit board 36 is, for example, a flexible circuit board.

As illustrated in FIG. 13, the opening 81 is provided substantially in the center of the third portion 41c. A part of the third portion 41c is disposed between the opening 81 and the first portion 41a. Another part of the third portion 41c is disposed between the opening 81 and the second portion 41b.

According to this structure, it is possible to improve the strength of the electronic apparatus 1. In this embodiment, a cutout portion 46 is not provided in the first portion 41a. Therefore, a reinforcing structure (e.g., a reinforcing structure with a shape close to a U-shape) is maintained over the entire length of the reinforcing member 41 and it is possible to improve the strength of the reinforcing member 41.

### Eighth Embodiment

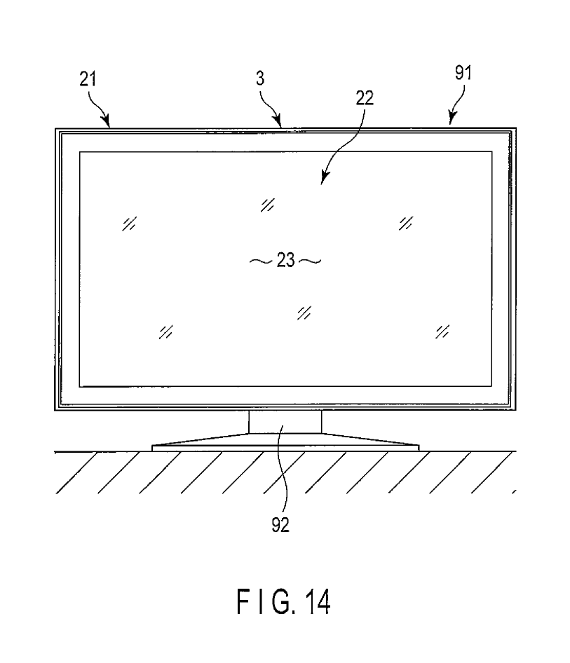

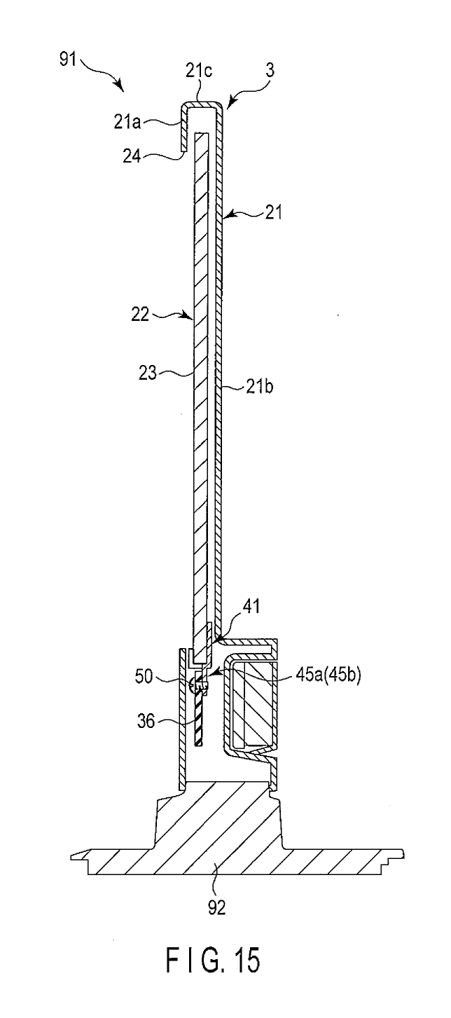

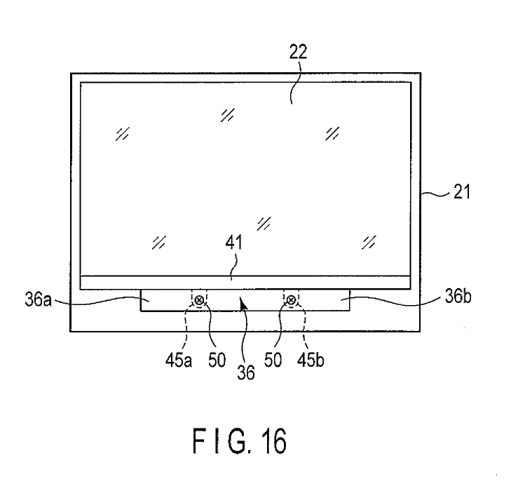

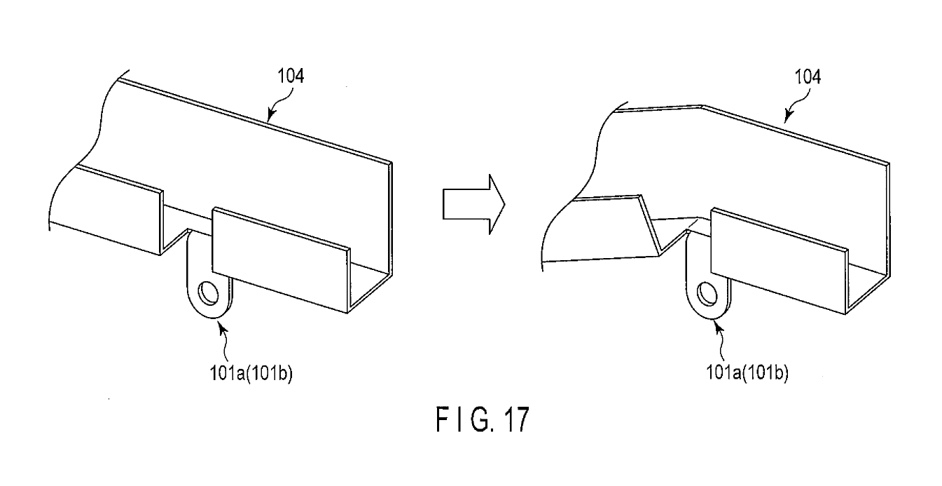

Next, an electronic apparatus 1 according to an eighth embodiment will be described with reference to FIGS. 14 to 16. In this embodiment, components having the same or similar functions as those in the first embodiment are denoted by the same reference numerals and the description thereof will not be repeated. In addition, structures other than the following structure are the same as those in the first embodiment.

FIGS. 14 to 16 illustrate a television 91 according to this embodiment. The television 91 is an example of an “electronic apparatus”. The television 91 includes a display unit 3 and a stand 92 supporting the display unit 3. The structure related to a reinforcing member 41 is the same as that in the first embodiment. That is, cutout portions 46 (supporting portions 45a and 45b) are provided in the reinforcing member 41 at positions corresponding to an inner region of a circuit board 36 than the end region.

According to this structure, similarly to the first embodiment, it is possible to improve the strength of the television. Therefore, the distance between supporting portions 45a and 45b and the edge of a housing 21 is large and an impact or stress applied to the housing 21 is less likely to be transmitted to the supporting portions 45a and 45b. As a result, the reinforcing member 41 can sufficiently protect a display device 22 and a defect is less likely to occur in the display device.

According to the first to eighth embodiments, it is possible to improve the strength of the electronic apparatus.

The embodiments are not limited to the above-described embodiments, but the components according to the above-described embodiments may be changed without departing from the scope and spirit of the invention. In addition, a plurality of components according to the above-described embodiments may be appropriately combined with each other to form various structures. For example, some of the components according to the above-described embodiments may be removed. Components according to different embodiments may be appropriately combined with each other.

In the first to eighth embodiments, the reinforcing member 41 includes the first to third portions 41a, 41b, and 41c. When sufficient rigidity can be ensured by an L-shaped reinforcing structure formed by the first portion 41a and the third portion 41c, the second portion 41b may not be provided. When sufficient rigidity can be ensured by an L-shaped reinforcing structure formed by the second portion 41b and the third portion 41c, the first portion 41a may not be provided. In the third, fourth, fifth, and sixth embodiments, the supporting portions 45a and 45b do not need to be provided at an inner region of the circuit board 36, but may be provided at the end region of the circuit board 36.

Next, some electronic apparatuses capable of improving strength as viewed from a different point will be described.

[a] an electrical apparatus comprises: (i) a housing; (ii) a display in the housing, the display comprising a first surface and a second surface, the first surface comprising a display screen, the second surface opposite to the first surface; (iii) a circuit board (i.e., module) in the housing; and (iv) a member attached to an end of the display, the member comprising a first portion facing the first surface of the display, a second portion facing the second surface of the display, and a third portion between the first portion and the second portion. The third portion comprises a supporting portion formed by cutting and bending a part of the third portion, the supporting portion configured to support the circuit board.

[b] an electronic apparatus comprises: (i) a housing; (ii) a display in the housing; (iii) a circuit board (i.e., module) in the housing, (iv) a member attached to an end of the display, the member comprising a cutout portion and configured to support the circuit board; and (v) a reinforcing component attached to the member and covering the cutout portion.

According to these structures, it is possible to maintain the reinforcing structure over the entire length of the reinforcing member 41 and improve the strength of the electronic apparatus.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A television comprising:
a housing;
a display in the housing, the display comprising a first surface and a second surface, the first surface comprising a display screen, the second surface opposite to the first surface;
a circuit board comprising a first component, the circuit board electrically connected to the display and not facing the first surface and the second surface of the display; and
a reinforcing portion attached to an end of the display, the reinforcing portion comprising a first portion facing the display, a second portion facing the display from an opposite side to the first portion, and a third portion between the first portion and the second portion,
wherein the first portion comprises a first supporting portion, the first supporting portion configured to support the circuit board, and
the first supporting portion is at a region of the circuit board farther inward than the first component in a direction substantially parallel to the end of the display.

2. The television of claim 1,
wherein the circuit board is within a thickness range of the display.

3. The television of claim 1,
wherein the first portion faces the first surface of the display.

4. The television of claim 1,
wherein the circuit board comprises a second component,
the reinforcing portion comprises a second supporting portion, the second supporting portion configured to support the circuit board, and
the first supporting portion and the second supporting portion are between the first component and the second component.

5. The television of claim 1, further comprising
a reinforcing component,
wherein the first supporting portion comprises a cutout portion, and
the reinforcing component is attached to a reinforcing member and covers the cutout portion.

6. A portable computer comprising:
a first housing;
a second housing;
a hinge configured to attach the first housing to the second housing;
a display in the second housing, the display comprising a first surface and a second surface, the first surface comprising a display screen, the second surface opposite to the first surface;
a circuit board comprising a component, the circuit board electrically connected to the display and not facing the first surface and the second surface of the display; and
a reinforcing portion attached to an end of the display, the reinforcing portion comprising a first portion facing the display, a second portion facing the display from an opposite side to the first portion, and a third portion between the first portion and the second portion,
wherein the first portion comprises a supporting portion, the supporting portion configured to support the circuit board, and
the supporting portion is a greater distance from an end of the circuit board than the component in a direction substantially parallel to the end of the display.

7. The portable computer of claim 6,
wherein the hinge comprises a fixing portion attached to the second housing, and
the supporting portion is a greater distance from the end of the circuit board than the fixing portion of the hinge in the direction substantially parallel to the end of the display.

8. The portable computer of claim 7,
wherein the fixing portion of the hinge is between the end of the circuit board and the supporting portion.

9. The portable computer of claim 6,
wherein the second housing comprises a protrusion that protrudes toward the first housing, a portion of the hinge is in the protrusion, the protrusion comprising a corner, and
the supporting portion is a greater distance from the end of the circuit board than the corner of the protrusion in the direction substantially parallel to the end of the display.

10. An electronic apparatus comprising:
a housing;
a display in the housing;
a module in the housing; and
a member attached to an end of the display, the member configured to support the module and comprising a cutout portion at an inner side of an end region of the module in a direction substantially parallel to the end of the display.
